(19) United States
(12) Patent Application Publication
(10) Pub. No.: US 2021/0008685 A1
(43) Pub. Date: Jan. 14, 2021

(54) CHEMICAL MECHANICAL POLISHING APPARATUS, CHEMICAL MECHANICAL POLISHING METHOD AND METHOD OF MANUFACTURING DISPLAY APPARATUS USING THE SAME

(71) Applicant: Samsung Display Co., LTD., Yongin-si (KR)

(72) Inventors: Jung-Gun NAM, Suwon-si (KR); Seung-Bae KANG, Suwon-si (KR); Heesung YANG, Seoul (KR); Bonggu KANG, Seoul (KR); Joon-Hwa BAE, Suwon-si (KR); Woo-Jin CHO, Yongin-si (KR); Byoung-Kwon CHOO, Hwaseong-si (KR)

(73) Assignee: Samsung Display Co., LTD., Yongin-si (KR)

(21) Appl. No.: 16/926,034

(22) Filed: Jul. 10, 2020

(30) Foreign Application Priority Data
Jul. 12, 2019 (KR) 10-2019-0084743

(51) Int. Cl. B24B 37/10; B24B 7/22; H01L 21/321

(52) U.S. Cl. CPC B24B 37/105; H01L 21/3212; B24B 7/228

(57) ABSTRACT

A method of manufacturing a display and a chemical mechanical polishing method which employ a chemical mechanical polishing apparatus that includes a conveyor belt to transfer a substrate, a polishing head disposed on the conveyor belt, and a body part which moves the polishing head and supplies a slurry to the polishing head. The polishing head includes a first polishing part including a first polishing pad surrounding a first slurry outlet, and a second polishing part surrounding the first polishing part and including a second polishing pad. A second slurry outlet is formed between the first polishing part and the second polishing part, and the first polishing part and the second polishing part are movable independently of each other in a direction substantially perpendicular to the substrate.

### CROSS-REFERENCE TO RELATED APPLICATION

This application claims priority to and benefits of Korean Patent Application No. 10-2019-0084743 under 35 U.S.C. § 119, filed in the Korean Intellectual Property Office on Jul. 12, 2019, the entire contents of which are incorporated herein by reference.

### BACKGROUND

### 1. Technical Field

Embodiments relate to a chemical mechanical polishing apparatus, a chemical mechanical polishing method and a method of manufacturing a display using the chemical mechanical polishing method. Embodiments also relate to a chemical mechanical polishing apparatus and a chemical mechanical polishing method for manufacturing a display, and a method of manufacturing a display using the chemical mechanical polishing method.

### 2. Description of the Related Art

Display devices that are small and light weight have been manufactured. A cathode ray tube (CRT) display has been manufactured because of performance and competitive pricing. However, the CRT display has a drawback because of its relatively large size and/or lack of portability. Therefore, displays such as plasma displays, liquid crystal displays, and organic light emitting displays have been favored because of their small size, their light weight or portability and their low-power-consumption.

Flexible displays are being developed, and the display may be manufactured by separating thin film layers from a carrier glass after forming thin film layers on the carrier glass. However, the thin film layers which may remain on the carrier glass are not easy to remove making to difficult to recycle the carrier glass and this causes problems in manufacturing and potentially contributes to increased costs.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments of the disclosure provide a chemical mechanical polishing apparatus.

One or more embodiments of the disclosure also provide a chemical mechanical polishing method.

One or more embodiments of the disclosure also provide a method of manufacturing a display device using the chemical mechanical polishing method.

According to an embodiment, a chemical mechanical polishing apparatus includes a conveyor belt to transfer a substrate, a polishing head disposed on the conveyor belt, and a body part connected to the polishing head, the body part moving the polishing head and supplying a slurry to the polishing head. The polishing head includes a first slurry outlet, a first polishing part including a first polishing pad surrounding the first slurry outlet, a second polishing part surrounding the first polishing part and including a second polishing pad. A second slurry outlet is disposed between the first polishing part and the second polishing part, wherein the first polishing part and the second polishing part are movable independently of each other in a direction substantially perpendicular to the substrate.

In an embodiment, the chemical mechanical polishing apparatus may further include a first rotating member connected to the first polishing part, and a second rotating member surrounding the first rotating member and connected to the second polishing part. The first slurry outlet may be formed along the first polishing part and the first rotating part. The second slurry outlet may be formed between the first polishing part and the second polishing part, and between the first rotating member and the second rotating member.

In an embodiment, the first polishing part may have a cylindrical shape, and the first polishing part and the second polishing part may be rotatable together or respectively.

In an embodiment, the chemical mechanical polishing apparatus may further include a third polishing part surrounding the second polishing part and including a third polishing pad.

In an embodiment, the chemical mechanical polishing apparatus may further include a third polishing part spaced apart from the first polishing part and including a third polishing pad. The second polishing part may be disposed between the first polishing part and the third polishing part. An area of the first polishing pad and an area of the third polishing pad may be different from each other.

In an embodiment, the chemical mechanical polishing apparatus may further include a supporting part disposed adjacent to the substrate on the conveyer belt to compensate for a step with the substrate.

In an embodiment, the thickness of the substrate may be approximately or about equal to the thickness of the supporting part.

In an embodiment, the first polishing pad may have a first area, the second polishing pad may have a second area. When the polishing head overlaps a substantially entire area of the substrate on a plan view, both the first polishing part and the second polishing part may contact the substrate to polish the substrate. When the polishing head partially overlaps the substrate on a plan view, the first polishing part may move vertically closer to the substrate than the second polishing part, so that only the first polishing part may contacts the substrate to polish the substrate.

In an embodiment, the chemical mechanical polishing apparatus may further include a third polishing pad having a third area wherein when the polishing head overlaps the substantially entire area of the substrate on a plan view, the first polishing part, the second polishing part, and the third polishing part may contact the substrate to polish the substrate.

According to an embodiment, a chemical mechanical polishing method includes loading a substrate on a conveyer belt, polishing an upper surface of the substrate by a chemical mechanical polishing apparatus comprising a polishing head disposed on the conveyer belt, wherein the polishing head includes a first slurry outlet, a first polishing part surrounding the first slurry outlet, and a second polishing part surrounding the first polishing part polishing the upper surface of the substrate with at least one of the first polishing part and the second polishing part, and unloading the substrate from the conveyer belt.

In an embodiment, the chemical mechanical polishing method may further include attaching a supporting part adjacent to the substrate on the conveyer belt to compensate for a step with the substrate.

In an embodiment, when the polishing head overlaps a substantially entire area of the substrate on a plan view, both the first polishing part and the second polishing part may contact the substrate to polish the substrate.

In an embodiment, the chemical mechanical polishing method may further include providing a third polishing part in the chemical mechanical polishing apparatus and polishing the upper surface of the substrate with the first polishing part, the second polishing part, and the third polishing part when the polishing head overlaps the substantially entire area of the substrate on a plan view.

In an embodiment, when the polishing head partially overlaps the substrate on a plan view, the first polishing part may move vertically closer to the substrate than the second polishing part, so that only the first polishing part may contact the substrate to polish the substrate.

According to an embodiment, a method of manufacturing a display includes forming a display device on a carrier substrate, separating the display device from the carrier substrate, removing a residual layer on the carrier substrate by a chemical mechanical polishing apparatus, removing an outer portion which remains at an edge portion on the carrier substrate by the chemical mechanical polishing apparatus, forming a new display device on the carrier substrate.

In an embodiment, the chemical mechanical polishing apparatus may include a first polishing part and a second polishing part. Removing the residual layer, may include polishing the carrier substrate with the first polishing part and the second polishing part.

In an embodiment, in removing the outer portion, may include moving the first polishing part vertically closer to the carrier substrate than the second polishing part, so that only the first polishing part may polish the carrier substrate to remove the outer portion.

In an embodiment, the outer portion may have a higher height than the residual layer.

In an embodiment, the method may further include loading the carrier substrate on a conveyer belt before removing the residual layer. Removing the residual layer, and removing the outer portion may be performed while the carrier substrate is transferred by the conveyer belt.

In an embodiment, the method may further include attaching a supporting part adjacent to the carrier substrate on the conveyer belt to compensate for a step with the carrier substrate.

In an embodiment, the chemical mechanical polishing apparatus may include a conveyor belt to transfer the carrier substrate, a polishing head disposed on the conveyor belt, and a body part which moves the polishing head and supplies a slurry to the polishing head. The polishing head may include a first polishing part and a second polishing part. A second slurry outlet may be formed between the first polishing part and the second polishing part, and the first polishing part and the second polishing part, and the method may further include moving the first polishing part and the second polishing part independently of each other in a direction substantially perpendicular to the carrier substrate.

In an embodiment, the method may further include forming the first polishing part to have a cylindrical shape. The first polishing part and the second polishing part may be rotatable together or respectively.

In an embodiment, forming the display device may include forming insulating layers, thin film transistors, circuit lines, organic light emitting diodes on the carrier substrate.

According to the embodiments, a chemical mechanical polishing apparatus may include a conveyor belt to transfer a substrate, a polishing head disposed on the conveyor belt, and a body part connected to the polishing head which moves the polishing head and supplies a slurry to the polishing head. The polishing head may include a first polishing part including a first slurry outlet and a first polishing pad surrounding the first slurry outlet; and a second polishing part surrounding the first polishing part and including a second polishing pad. A second slurry outlet may be formed between the first polishing part and the second polishing part, and the first polishing part and the second polishing part may be movable independently of each other in a direction substantially perpendicular to the substrate.

When the polishing head is completely overlapped with the substrate on a plan view, that is, when performing a chemical mechanical polishing process for a large area of a central portion of the substrate, all of the first to third polishing parts may be used, resulting in a large area of the substrate being polished. On the other hand, when the polishing head partially overlaps the substrate on a plan view, that is, when the chemical mechanical polishing process is performed on a local area of an edge portion of the substrate, only the first polishing part, or the first and second polishing parts is used, so that a local area smaller than the large area of the substrate may be polished.

In an embodiment, including a supporting part attached on the conveyor belt to compensate for a separation step with the substrate, may prevent excessive grinding at the edge portion or portions of the substrate.

In an embodiment, a slurry for chemical mechanical polishing may be discharged through the first slurry outlet of the first polishing part, a second slurry outlet between the first polishing part and the second polishing part, and a third slurry outlet between the second polishing part and the third polishing part. Thus, the slurry may be efficiently and directly supplied between the substrate to be worked upon and the polishing head. As another example, the second slurry outlet and the third slurry outlet may be formed or disposed in spaces between the first polishing part and the second polishing part, and between the second polishing part and the third polishing part, respectively, instead of forming a separate flow path, so that a structure of the chemical mechanical polishing apparatus may be simplified.

It is to be understood that both the foregoing general description and the following detailed description are explanatory and are intended to provide further explanation of the disclosure as claimed.

### BRIEF DESCRIPTION OF THE DRAWINGS

The above and other features of the disclosure will become more apparent by describing in detail embodiments thereof with reference to the accompanying drawings, in which:

FIG. 1 is a schematic side view illustrating a chemical mechanical polishing apparatus according to an embodiment;

FIG. 2 is a partially enlarged view illustrating a polishing head and its relationship to a supporting part on the conveyor belt of the chemical mechanical polishing apparatus of FIG. 1;

FIG. 3 is a plan view illustrating a polishing head and a substrate, a support portion around the substrate of the chemical mechanical polishing apparatus of FIG. 1;

FIG. 4 is a schematic cross-sectional view illustrating the polishing head of the chemical mechanical polishing apparatus of FIG. 1;

FIG. 5 is a perspective view illustrating a lower surface of the polishing head of FIG. 4;

FIGS. 6A through 6C are schematic cross-sectional views illustrating an operation of the polishing head of FIG. 4;

FIG. 7 is a plan view illustrating a lower surface of the polishing head of the chemical mechanical polishing apparatus according to an embodiment;

FIG. 8 is a plan view illustrating a lower surface of the polishing head of the chemical mechanical polishing apparatus according to an embodiment;

FIG. 9A to 9F are schematic cross-sectional views illustrating a method of manufacturing a display using a chemical mechanical polishing apparatus and a chemical mechanical polishing method, according to an embodiment; and

FIG. 10 is a flowchart illustrating a method of manufacturing a display device using a chemical mechanical polishing apparatus and a chemical mechanical polishing method according to an embodiment.

### DETAILED DESCRIPTION OF THE EMBODIMENTS

Although the invention may be modified in various manners and have additional embodiments, embodiments are illustrated in the accompanying drawings and will be mainly described in the specification. However, the scope of the disclosure is not limited to the embodiments in the accompanying drawings and the specification and should be construed as including all the changes, equivalents and substitutions included in the spirit and scope of the disclosure.

Some of the parts which are not associated with the description may not be provided in order to describe embodiments of the disclosure and like reference numerals refer to like elements throughout the specification.

In the drawings, sizes and thicknesses of elements may be enlarged for clarity and ease of description thereof. However, the disclosure is not limited to the illustrated sizes and thicknesses. In the drawings, the thicknesses of layers, films, panels, regions, and other elements may be exaggerated for clarity. In the drawings, for better understanding and ease of description, the thicknesses of some layers and areas may be exaggerated.

Further, in the specification, the phrase “in a plan view” means when an object portion is viewed from above, and the phrase “in a schematic cross-sectional view” means when a schematic cross-section taken by vertically cutting an object portion is viewed from the side.

Additionally, the terms “overlap” or “overlapped” mean that a first object may be above or below or to a side of a second object, and vice versa. Additionally, the term “overlap” may include layer, stack, face or facing, extending over, covering or partly covering or any other suitable term as would be appreciated and understood by those of ordinary skill in the art. The terms “face” and “facing” mean that a first element may directly or indirectly oppose a second element. In a case in which a third element intervenes between the first and second element, the first and second element may be understood as being indirectly opposed to one another, although still facing each other. When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

When a layer, film, region, substrate, or area, is referred to as being “on” another layer, film, region, substrate, or area, it may be directly on the other film, region, substrate, or area, or intervening films, regions, substrates, or areas, may be present therebetween. Conversely, when a layer, film, region, substrate, or area, is referred to as being “directly on” another layer, film, region, substrate, or area, intervening layers, films, regions, substrates, or areas, may be absent therebetween. Further when a layer, film, region, substrate, or area, is referred to as being “below” another layer, film, region, substrate, or area, it may be directly below the other layer, film, region, substrate, or area, or intervening layers, films, regions, substrates, or areas, may be present therebetween. Conversely, when a layer, film, region, substrate, or area, is referred to as being “directly below” another layer, film, region, substrate, or area, intervening layers, films, regions, substrates, or areas, may be absent therebetween. Further, “over” or “on” may include positioning on or below an object and does not necessarily imply a direction based upon gravity.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

Throughout the specification, when an element is referred to as being “connected” to another element, the element may be “directly connected” to another element, or “electrically connected” to another element with one or more intervening elements interposed therebetween. It will be further understood that when the terms “comprises,” “comprising,” “includes” and/or “including” are used in this specification, they or it may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 5% of the stated value.

Unless otherwise defined, all terms used herein (including technical and scientific terms) have the same meaning as commonly understood by those skilled in the art to which this invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, the disclosure will be explained in detail with reference to the accompanying drawings.

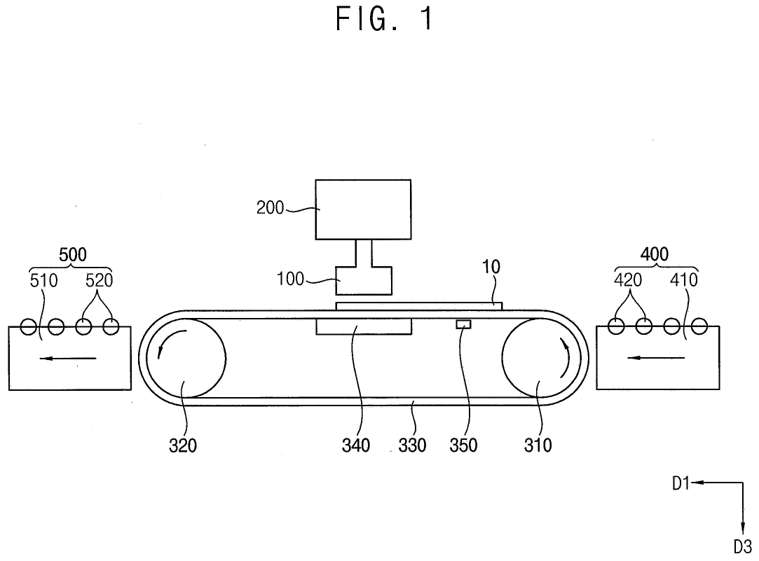

FIG. 1 is a schematic side view illustrating a chemical mechanical polishing apparatus according to an embodiment.

Referring to FIG. 1, the chemical mechanical polishing apparatus may include a first transferring part 400, a first conveyor driving part 310, a second conveyor driving part 320, a conveyor belt 330, a supporting part 340, a tension adjusting part 350, a polishing head 100, a body part 200 and a second transferring part 500.

The first transferring part 400 may load a substrate 10 onto the conveyor belt 330. The first transferring part 400 may include rollers 420 for transferring the substrate 10 and a roller driver 410 for rotating the rollers 420. For example, the roller driver 410 may rotate the rollers 420 to transfer the substrate 10 in a first direction D1 to load the substrate 10 onto the conveyor belt 330.

The first conveyor driving part 310 and the second conveyor driving part 320 may be driving rollers spaced apart from each other in the first direction D1. The conveyor belt 330 may be rotated by the first and second conveyor driving parts 310 and 320 to transfer the substrate 10 in the first direction D1.

The supporting part 340 may be located below the polishing head 100. The conveyor belt 330 may be located between the supporting part 340 and the polishing head 100.

The tension adjusting part 350 may adjust the tension of the conveyor belt 330.

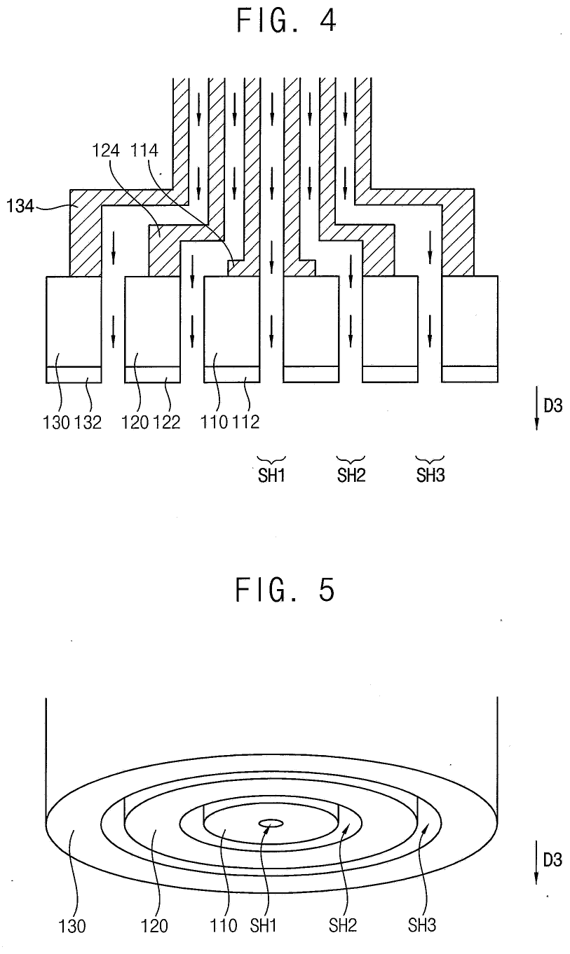

The polishing head 100 may be disposed or positioned on the conveyor belt 330 and the supporting part 340, causing a friction in contact with the substrate 10 such that an upper surface of the substrate 10 can be mechanically polished. During the mechanical polishing of the substrate 10, a slurry for chemical polishing may be supplied together with the mechanical polishing such that a chemical mechanical polishing (CMP) process can be performed. The slurry may be supplied through an outlet or outlets of the polishing head 100 to the substrate 10. The slurry outlets may be illustrated for example in FIG. 4 as first slurry outlet SH1, second slurry outlet SH2, and third slurry outlet SH3. The slurry may be a composition comprising an abrasive and a solvent.

The polishing head 100 may be movable along a third direction D3, which may be substantially perpendicular to the substrate 10. The polishing head 100 may be moved to a selected position on the substrate 10 by moving in the first direction D1 and or the third direction as illustrated for example in FIG. 1. The polishing head 100 may also be configured to be rotated.

The body part 200 may be connected to the polishing head 100 to move and rotate the polishing head 100 and supply the slurry to the polishing head 100.

The second transferring part 500 may include rollers 520 for transferring the substrate 10 and a roller driver 510 for rotating the rollers 520. For example, the roller driver 510 rotates the rollers 520 to transfer the substrate 10 in the first direction D1, thereby moving the substrate 10 from the conveyor belt 330 for unloading the substrate 10.

In general, a chemical mechanical polishing (CMP) process is a process used for planarization or for polishing of a semiconductor wafer. In the CMP process, fine particles for mechanical polishing and a slurry which includes chemicals for etching, dissolving, and/or oxidizing a surface of the semiconductor wafer are supplied, and a polishing pad or pads rotates or rotate for chemically and mechanically polishing the surface of the semiconductor wafer.

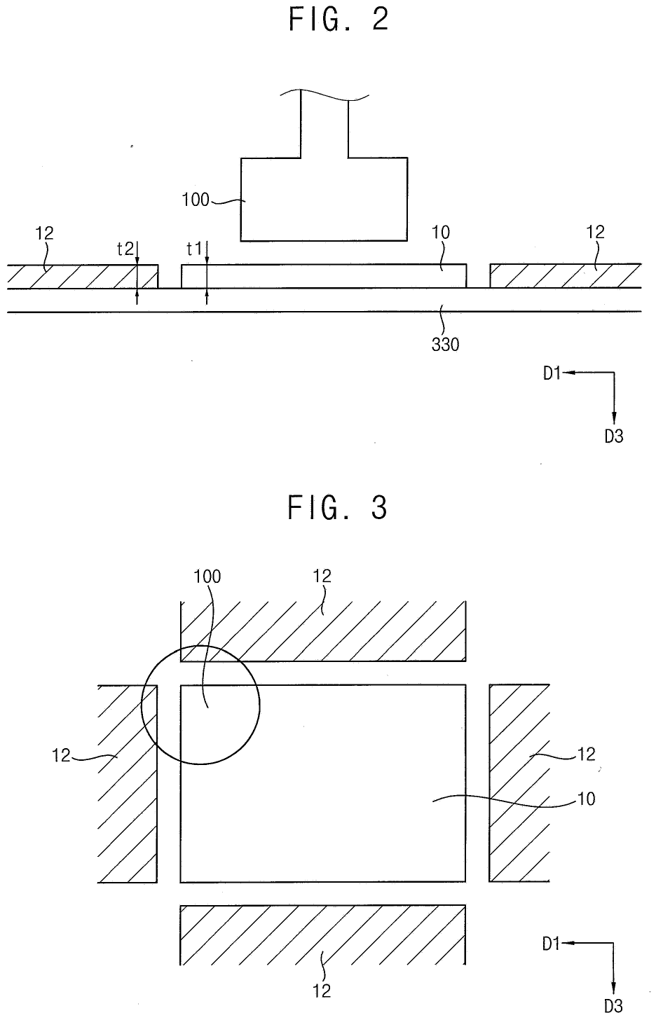

In the disclosure, by applying a chemical mechanical polishing process on a transportable substrate as opposed to a fixed wafer, process speed, process efficiency and process quality of the chemical mechanical polishing process can be improved. Further detailed descriptions thereof will be described later with reference to FIGS. 2 to 5.

FIG. 2 is a partially enlarged view illustrating a polishing head and its relationship to the substrate on the conveyor belt of the chemical mechanical polishing apparatus of FIG. 1. FIG. 3 is a plan view illustrating a polishing head and a substrate, and a support portion around the substrate of the chemical mechanical polishing apparatus of FIG. 1. FIG. 4 is a schematic cross-sectional view illustrating the polishing head of the chemical mechanical polishing apparatus of FIG. 1. FIG. 5 is a perspective view illustrating a lower surface of the polishing head of FIG. 4.

Referring to FIGS. 2 to 5, the polishing head 100 may include a first polishing part 110 including a first polishing pad 112 and a second polishing part 120 including a second polishing pad 122, a third polishing part 130 including a third polishing pad 132, a first rotating member 114, a second rotating member 124, a third rotating member 134, and a first slurry outlet SH1, a second slurry outlet SH2 and a third slurry outlet SH3. It should be understood that the number of slurry outlets is not limited to that which is shown in the drawings and any number of slurry outlets may be included within the spirit and scope of the disclosure. The first through third rotating members, 114, 124 and 134, may be rods, poles, or attachments or other suitable structures within the spirit and scope of the disclosure. The shape and or configuration of the first through third rotating members, 114, 124 and 134 is not limited to that which is illustrated in the drawings and may be any shape or configuration within the spirit and scope of the disclosure. For example, the first through third rotating members, 114, 124 and 134 may have a substantially bent shape or L-shape in a schematic cross-sectional view or may be substantially cylindrical.

The first polishing part 110 may have a cylindrical shape. The first polishing part 110 may be connected to the first rotating member 114 to be rotated by a rotation of the first rotating member 114. The first through third polishing parts, 110, 120 and 130 may have different areas with respect to each other. For example, the first polishing part 110 may have a smaller area than the second polishing part 120 and the third polishing part 130 may have a larger area than the second 120 or first polishing part 110. The first through third polishing parts, 110, 120 and 130 may have a disk-like shape in a perspective view. The first through third polishing pads 112, 122 and 132 may have the same, or similar, or different areas with respect to each other.

The first polishing pad 112 may be attached to a lower surface of the first polishing part 110 and may have an annular or substantially circular shape. The first polishing pad 112 may be provided to be detachably attached from under the first polishing part 110. The first polishing pad 112 may be made of a nonwoven fabric, a foamed polyurethane, or other suitable materials within the spirit and scope of the disclosure.

As shown in FIG. 4, the first slurry outlet SH1 may be formed through or along the first polishing part 110 and the first rotating member 114 to supply a slurry between the first polishing pad 112 and the substrate 10.

In the same or similar manner, the second slurry outlet SH2 may be formed through or along the second polishing part 120 and the second rotating member 124 to supply a slurry between the second polishing pad 122 and the substrate 10.

The second polishing part 120 may surround the first polishing part 110 and have an annular or a ring-shaped extended pillar shape. The second polishing part 120 may be connected to the second rotating member 124 surrounding the first rotating member 114 to be rotated by the second rotating member 124.

The second polishing pad 122 may be attached to a lower surface of the second polishing part 120 and may have an annular or substantially ring or circular shape. The second polishing pad 122 may be provided to be detachably attached under the second polishing part 120. The second polishing pad 122 may be made of a nonwoven fabric, a foamed polyurethane, or other suitable materials within the spirit and scope of the disclosure.

The third polishing part 130 may surround the second polishing part 120 and have an annular or a ring-shaped extended pillar shape. The third polishing part 130 may be connected to the third rotating member 134 surrounding the second rotating member 124 to be rotated by the third rotating member 134.

The third polishing pad 132 may be attached to a lower surface of the third polishing part 130 and may have a substantially ring shape. The third polishing pad 132 may be provided to be detachably attached under the third polishing part 130. The third polishing pad 132 may be made of a nonwoven fabric, a foamed polyurethane, or other suitable materials within the spirit and scope of the disclosure.

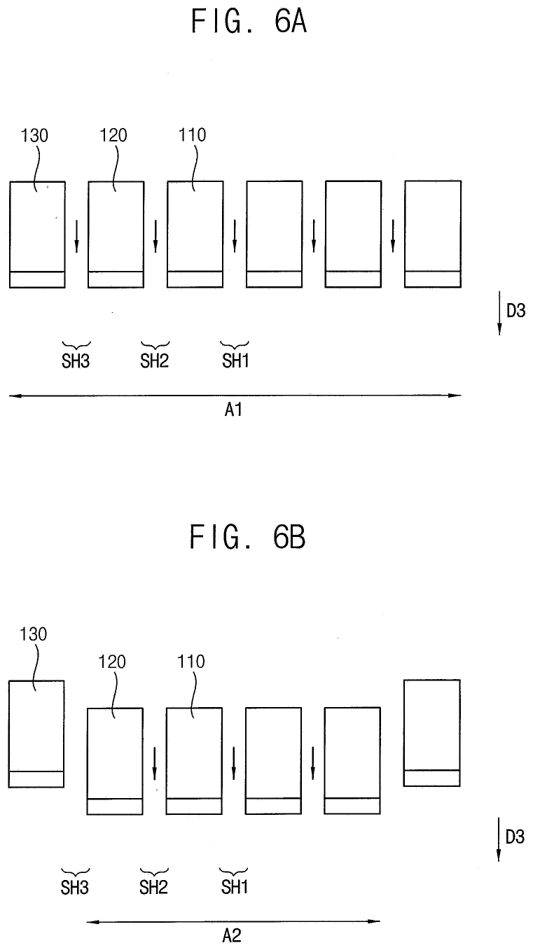

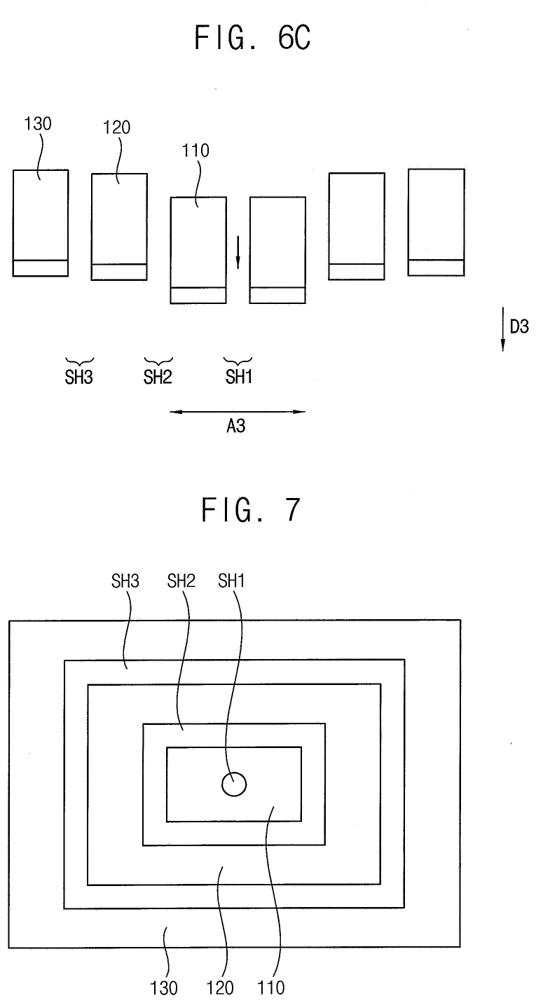

For example, the first polishing part 110, the second polishing part 120 and the third polishing part 130 may be provided to be rotatable together or each rotatable independently. Each of the first polishing part 110, the second polishing part 120, and the third polishing part 130 may independently move along a third direction D3 that may be substantially perpendicular to the substrate 10, so that the polishing area can be changed to apply to various areas of a substrate. An example of the above is illustrated in FIGS. 6A through 6C.

When the polishing head 100 completely overlaps with the substrate 10 in a plan view, all of the first polishing part 110, the second polishing part 120, and the third polishing part 130 may be in contact with the substrate 10 to polish the substrate 10 as illustrated in FIG. 6A. The completely overlapping may include that the polishing head 100 may overlap a substantially entire area of the substrate 10. When the polishing head 100 partially overlaps with the substrate 10 in a plan view, the first polishing part 110 may move vertically closer to the substrate 10 than the second polishing part 120 and the third polishing part 130, so that only the first polishing part 110 may contact the substrate 10 to polish the substrate 10 as illustrated in FIG. 6C. In FIG. 6B, the first and second polishing parts 110 and 120 may be vertically moved closer to the substrate 10 than the third polishing part 130, so that first and second polishing parts 110 and 120 may contact the substrate 10 to polish the substrate 10.

In carrying out a chemical mechanical polishing process on a substrate, when a large polishing pad is used, chemical mechanical polishing is possible for a large area. However, the polishing of the substrate with the large polishing pad may not be precise and suitable for polishing local or smaller protrusions. On the other hand, when using a small polishing pad, the small polishing pad is advantageous in polishing the local or smaller protrusions, however, the polishing speed may be reduced.

According to an embodiment, the first polishing part, the second polishing part and the third polishing part of the polishing head of the chemical mechanical polishing apparatus may be independently movable in the vertical direction. Accordingly, it is possible to perform chemical mechanical polishing for an appropriate range of regions or areas of a substrate depending on the polishing position and the characteristics of the substrate upon which to be worked.

For example, the polishing head may be completely overlapped with the substrate or substantially overlapped with the substrate on a plan view. When performing a chemical mechanical polishing process for a large area of a central portion of the substrate, all of the first to third polishing parts may be used, allowing large area polishing. On the other hand, when the polishing head partially overlaps the substrate on a plan view, that is, when the chemical mechanical polishing process is performed on a local area of an edge portion of the substrate, only the first polishing part, or the first and second polishing parts may be used, so that a local area that is smaller than the large area of the substrate can be polished.

At this time, by a supporting part 12 attached on the conveyor belt to compensate for a step with the substrate, excessive grinding at the edge portions of the substrate can be prevented. The supporting part 12 may be coplanar with the substrate 10 such that the thickness of the substrate t1 may be approximately or about equal to the thickness of the supporting part t2 thus preventing the polishing head 100 from grinding around the edges of the substrate 10. The above description can be appreciated with reference to FIG. 2.

A slurry for chemical mechanical polishing may be discharged through the first slurry outlet of the first polishing part, a second slurry outlet between the first polishing part and the second polishing part, and a third slurry outlet between the second polishing part and the third polishing part. Thus, the slurry can be efficiently and directly supplied between the substrate to be worked upon and the polishing head. The second slurry outlet and the third slurry outlet may be formed or disposed in spaces between the first polishing part and the second polishing part, and between the second polishing part and the third polishing part, respectively, instead of forming a separate flow path, so that a structure of the chemical mechanical polishing apparatus can be simplified.

FIGS. 6A through 6C are schematic cross-sectional views illustrating an operation of the polishing head of FIG. 4.

Referring to FIG. 6A, when all of the first polishing part 110, the second polishing part 120, and the third polishing part 130 may be used for polishing, a large area A1 of the substrate may be polished at one time. The slurry may be supplied through the first slurry outlet SH1, the second slurry outlet SH2, and the third slurry outlet SH3.

Referring to FIG. 6B, the first and second polishing parts 110 and 120 may be vertically moved closer to the substrate 10 than the third polishing part 130, so that only the first and second polishing parts 110 and 120 are used for polishing, and a middle area A2 of the substrate may be polished at one time. For example, the slurry may be supplied through the first slurry outlet SH1 and the second slurry outlet SH2.

Referring to FIG. 6C, the first polishing part 110 may be vertically moved closer to the substrate 10 than the second polishing part 120 and the third polishing part 130, so that only the first polishing part 110 is used for polishing, and it is possible to polish a small area A3 of the substrate at one time. For example, the slurry may be supplied through the first slurry outlet SH1.

FIG. 7 is a plan view illustrating a lower surface of the polishing head of the chemical mechanical polishing apparatus according to an embodiment.

Referring to FIG. 7, the chemical mechanical polishing apparatus is substantially the same as the chemical mechanical polishing apparatus described in FIGS. 1 to 5 except for the shape of a polishing head 100. Therefore, description will be omitted with respect to the same features that were described above.

A lower surface of the polishing head 100 may have a substantially rectangular shape. The polishing head 100 may be larger than one side of the substrate. The polishing head may polish the substrate through reciprocating motion and/or curved motion on the substrate instead of the rotational motion.

As shown in the FIG. 7, the lower surface of the first polishing part 110 may have a substantially rectangular shape. A second polishing part 120 may have a substantially rectangular ring shape surrounding the first polishing part 110. A third polishing part 130 may have a substantially rectangular ring shape surrounding the second polishing part 120.

The first slurry outlet SH1 may be formed in the first polishing part 110. The second slurry outlet SH2 may be formed in a substantially quadrangular shape between the first polishing part 110 and the second polishing part 120. The third slurry outlet SH3 may be formed in a substantially quadrangular shape between the second polishing part 120 and the third polishing part 130.

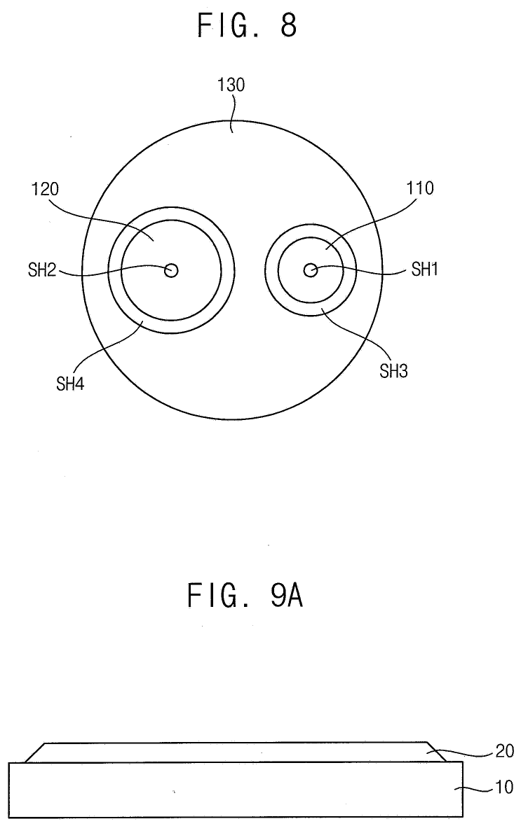

FIG. 8 is a plan view illustrating a lower surface of the polishing head of the chemical mechanical polishing apparatus according to an embodiment.

Referring to FIG. 8, the chemical mechanical polishing apparatus is substantially the same as the chemical mechanical polishing apparatus described in FIGS. 1 to 5 except for a shape of the polishing head 100. Therefore, description will be omitted with respect to the same features that were described above.

The lower surface of the polishing head 100 may be substantially annular or circular. A lower surface of the first polishing part 110 and a lower surface of the second polishing part 120 may have substantially annular or circular shapes having different sizes. The second polishing part 120 may be spaced apart from the first polishing part 110. The third polishing part 130 may surround the first polishing part 110 and the second polishing part 120.

A first slurry outlet SH1 may be formed in the first polishing part 110, and a second slurry outlet SH2 may be formed in the second polishing part 120. A third slurry outlet SH3 may be formed between the first polishing part 110 and the third polishing part 130. A fourth slurry outlet SH4 may be formed between the second polishing part 120 and the third polishing part 130.

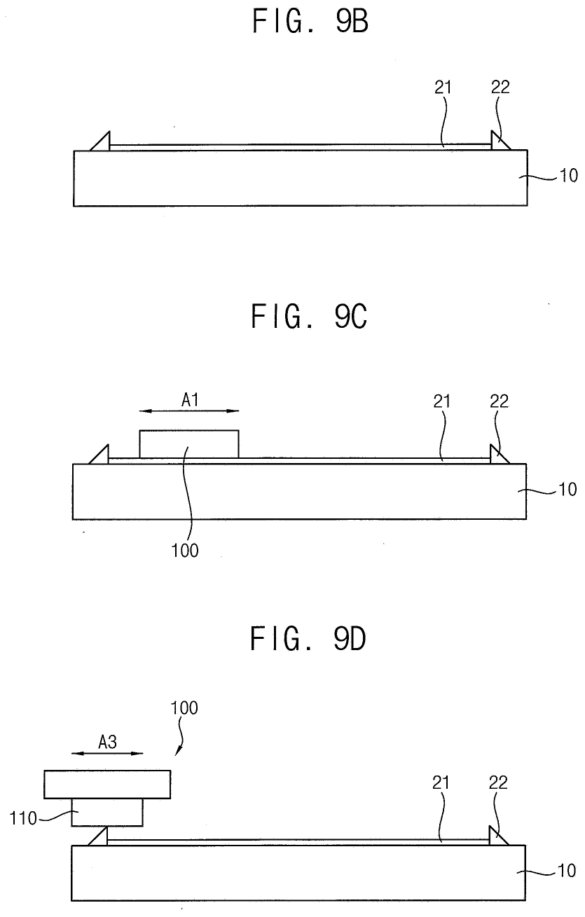

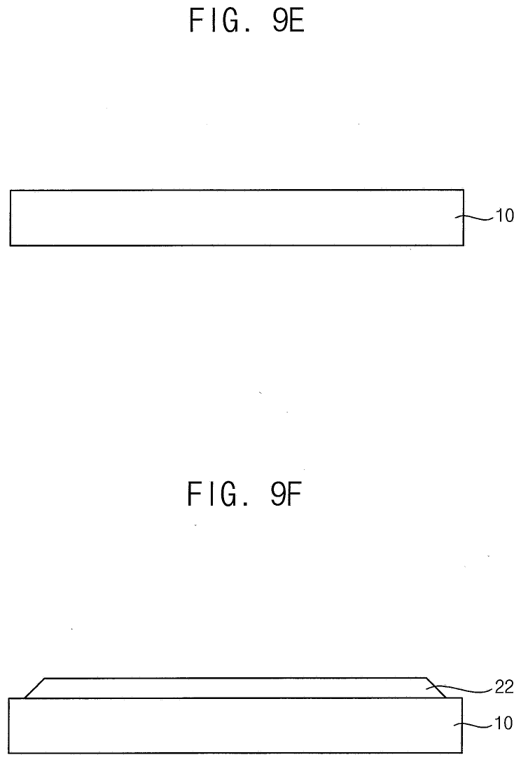

FIG. 9A to 9F are schematic cross-sectional views illustrating a method of manufacturing a display using a chemical mechanical polishing apparatus and a chemical mechanical polishing method, according to an embodiment.

Referring to FIG. 9A, the display device 20 may be formed on the carrier substrate 10. For example, the display device 20 may be a flexible display. The display device 20 may be obtained by forming thin films on the carrier substrate 10. For example, the display device 20 may include insulating layers, thin film transistors, circuit lines, organic light emitting diodes, and the like. The display device 20 may be formed by various methods as may be appreciated and understood by those of ordinary skill in the art.

Referring to FIG. 9B, the display device 20 on the carrier substrate 10 may be separated from the carrier substrate 10. In this case, a portion of the thin film of the display device 20 may remain on the carrier substrate 10. For example, in the separation of the display device 20, a residual layer 21 may remain on the carrier substrate 10, and an outer portion 22 that corresponds to an edge of the display device 20 may remain. The residual layer 21 may be a portion of a lower layer of the display device 20. The outer portion 22 may be a structure in which the thin film layers of an edge portion of the display device 20 are stacked. Accordingly, the outer portion 22 may have a height higher than that of the residual layer 21.

Referring to FIG. 9C, the residual layer 21 on the carrier substrate 10 may be removed. The chemical mechanical polishing apparatus according to an embodiment can be used. The chemical mechanical polishing apparatus may include a conveyor belt for transporting the carrier substrate 10, a polishing head 100 disposed on the conveyor belt, and a body part for moving the polishing head 100 and supplying a slurry to the polishing head 100. The polishing head 100 may include a first polishing part wherein a first slurry outlet may be formed therein and including a first polishing pad surrounding the first slurry outlet, and a second polishing part surrounding the first polishing part and including a second polishing pad, and a third polishing surrounding the second polishing part and including a third polishing pad.

As an example, the polishing head 100 may have a first slurry outlet formed therein, and may include a first polishing part including a first polishing pad surrounding the first slurry outlet, a second polishing part including a second polishing pad surrounding the first polishing part, and a third polishing part including a third polishing pad surrounding the second polishing part. A second slurry outlet may be formed between the first polishing part and the second polishing part. A third slurry outlet may be formed between the second polishing part and the third polishing part. The first polishing part, the second polishing part, and the third polishing part 130 may be movable independently of each other in a direction substantially perpendicular to the carrier substrate 10.

In this case, the residual layer 21 may remain on the carrier substrate 10 so that the first polishing part, the second polishing part, and the third polishing part may be used for polishing for a large area polishing. In this case, a large area of the substrate can be polished at once as illustrated for example as A1 of FIG. 6A. In this case, the slurry may be supplied through the first slurry outlet, the second slurry outlet, and the third slurry outlet.

Referring to FIG. 9D, the outer portion 22 on the carrier substrate 10 may be removed. In this case, the chemical mechanical polishing apparatus may be used to remove the residual layer 21. Since the outer portion 22 remains on the carrier substrate 10 at the edge portion thereof, and is formed at a relatively higher height than the residual layer 21, the first polishing part may move vertically to be closer to the substrate 10 than the second polishing part and the third polishing part, so that only the first polishing part can be used for polishing, and a small area can be polished as illustrated as A3 of FIG. 6C. In this case, the slurry may be supplied through the first slurry outlet.

Referring to FIGS. 9E and 9F, all of the remaining layer and the outer portion remaining on the carrier substrate 10 are removed, and the carrier substrate 10 may be used to form a new display device 22. The new display device 22 may be formed on the carrier substrate 10 from which the residual layer and the outer portion are removed.

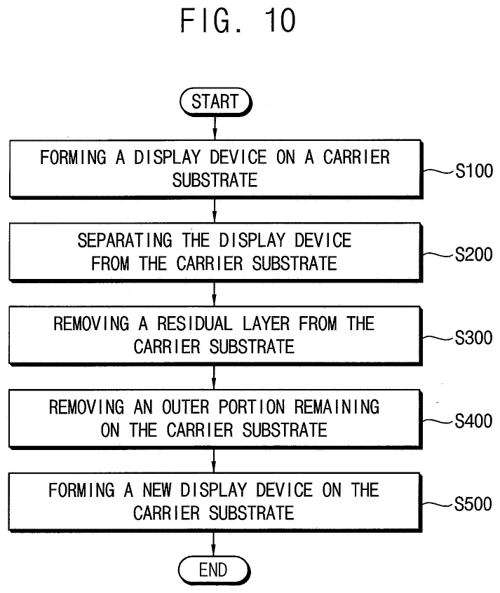

FIG. 10 is a flowchart illustrating a method of manufacturing a display device using a chemical mechanical polishing apparatus and a chemical mechanical polishing method according to an embodiment.

Referring to FIG. 10, the method of manufacturing a display device may include forming a display device on a carrier substrate (S100), separating the display device from the carrier substrate (S200), removing a residual layer from the carrier substrate (S300), removing an outer portion remaining on the carrier substrate (S400), and forming a new display device on the carrier substrate (S500). The display device manufactured by the method may include a flexible display.

According to the embodiments, a chemical mechanical polishing apparatus includes a conveyor belt to transfer a substrate, a polishing head disposed on the conveyor belt, and a body part which moves the polishing head and supplies a slurry to the polishing head. The polishing head may include a first polishing part wherein a first slurry outlet may be formed including a first polishing pad surrounding the first slurry outlet; and a second polishing part surrounding the first polishing part and including a second polishing pad. A second slurry outlet may be formed between the first polishing part and the second polishing part, and the first polishing part and the second polishing part may be movable independently of each other in a direction perpendicular to the substrate.

When the polishing head is completely or substantially overlapped with the substrate on a plan view, the chemical mechanical polishing process may be performed for a large area of a central portion of the substrate such that all of the first to third polishing parts are used to polish the large area. On the other hand, when the polishing head partially overlaps the substrate on a plan view, the chemical mechanical polishing process is performed on a local area of an edge portion of the substrate such that only the first polishing part or the second polishing parts may be used, so that a local area smaller than the large area can be polished.

By a supporting part attached on the conveyor belt to compensate for a step with the substrate, excessive grinding at the edge portion of the substrate may be prevented.

A slurry for chemical mechanical polishing may be discharged through the first slurry outlet of the first polishing part, the second slurry outlet between the first polishing part and the second polishing part, and/or the third slurry outlet between the second polishing part and the third polishing portion. Thus, the slurry can be efficiently and directly supplied between the substrate and the polishing head. In other embodiments, the second slurry outlet and the third slurry outlet may be formed or implemented with spaces between the first polishing part and the second polishing part, and between the second polishing part and the third polishing part, instead of forming a separate flow path, so that a structure of the chemical mechanical polishing apparatus can be simplified.

The disclosure may be applicable to organic light emitting display devices and various electronic devices including the same. For example, the disclosure can be applied to manufacturing a mobile phone, a smart phone, a video phone, a smart pad, a smart watch, a tablet PC, a vehicle navigation system, a television, a computer monitor, a notebook, and the like. However, the list is not exhaustive and may include other display devices within the spirit and scope of the disclosure.

The foregoing is illustrative of the disclosure and is not to be construed as limiting thereof. Although a few embodiments of the disclosure have been described, those skilled in the art will readily appreciate that many modifications are possible in the embodiments without materially departing from the novel teachings and advantages of the disclosure. Accordingly, all such modifications are intended to be included within the scope of the disclosure as defined in the claims. Therefore, it is to be understood that the foregoing is illustrative of the disclosure and is not to be construed as limited to the specific embodiments disclosed, and that modifications to the disclosed embodiments, as well as other embodiments, are intended to be included within the scope of the appended claims. The disclosure is defined by the following claims, with equivalents of the claims to be included therein.

What is claimed is:

1. A chemical mechanical polishing apparatus, comprising:
a conveyor belt to transfer a substrate;
a polishing head disposed on the conveyor belt; and
a body part connected to the polishing head, the body part moving the polishing head and supplying a slurry to the polishing head, and
wherein the polishing head comprises:
a first slurry outlet;
a first polishing part including a first polishing pad surrounding the first slurry outlet;
a second polishing part surrounding the first polishing part and including a second polishing pad; and
a second slurry outlet disposed between the first polishing part and the second polishing part,
wherein the first polishing part and the second polishing part are movable independently of each other in a direction substantially perpendicular to the substrate.

2. The chemical mechanical polishing apparatus of claim 1, further comprising:
a first rotating member connected to the first polishing part; and
a second rotating member surrounding the first rotating member and connected to the second polishing part, wherein
the first slurry outlet is formed along the first polishing part and the first rotating part, and
the second slurry outlet is formed between the first polishing part and the second polishing part, and between the first rotating member and the second rotating member.

3. The chemical mechanical polishing apparatus of claim 2, wherein
the first polishing part has a cylindrical shape, and
the first polishing part and the second polishing part are rotatable together or respectively.

4. The chemical mechanical polishing apparatus of claim 1, further comprising:
a third polishing part surrounding the second polishing part and including a third polishing pad.

5. The chemical mechanical polishing apparatus of claim 1, further comprising:
a third polishing part spaced apart from the first polishing part and including a third polishing pad, wherein
the second polishing part disposed between the first polishing part and the third polishing part, and
an area of the first polishing pad and an area of the third polishing pad are different from each other.

6. The chemical mechanical polishing apparatus of claim 1, further comprising:
a supporting part disposed adjacent to the substrate on the conveyer belt to compensate for a step with the substrate.

7. The chemical mechanical polishing apparatus of claim 6, wherein a thickness of the substrate is approximately equal to a thickness of the supporting part.

8. The chemical mechanical polishing apparatus of claim 1, wherein
the first polishing pad has a first area,
the second polishing pad has a second area,
when the polishing head overlaps a substantially entire area of the substrate on a plan view, both the first polishing part and the second polishing part contact the substrate to polish the substrate, and
when the polishing head partially overlaps the substrate on a plan view, the first polishing part moves vertically closer to the substrate than the second polishing part, so that only the first polishing part contacts the substrate to polish the substrate.

9. The chemical mechanical polishing apparatus of claim 8, further comprising a third polishing pad having a third area, wherein
when the polishing head overlaps the substantially entire area of the substrate on a plan view, the first polishing part, the second polishing part, and the third polishing part contact the substrate to polish the substrate.

10. A chemical mechanical polishing method, comprising:
loading a substrate on a conveyer belt;
polishing an upper surface of the substrate by a chemical mechanical polishing apparatus comprising a polishing head disposed on the conveyer belt, wherein the polishing head includes a first slurry outlet, a first polishing part surrounding the first slurry outlet, and a second polishing part surrounding the first polishing part;
polishing the upper surface of the substrate with at least one of the first polishing part and the second polishing part; and
unloading the substrate from the conveyer belt.

11. The chemical mechanical polishing method of claim 10, further comprising:
attaching a supporting part adjacent to the substrate on the conveyer belt to compensate for a step with the substrate.

12. The chemical mechanical polishing method of claim 10, wherein when the polishing head overlaps a substantially entire area of the substrate on a plan view, both the first polishing part and the second polishing part contact the substrate to polish the substrate.

13. The chemical mechanical polishing method of claim 12, further comprising:
providing a third polishing part in the chemical mechanical polishing apparatus; and
polishing the upper surface of the substrate with the first polishing part, the second polishing part, and the third polishing part when the polishing head overlaps the substantially entire area of the substrate on a plan view.

14. The chemical mechanical polishing method of claim 10, wherein when the polishing head partially overlaps the substrate on a plan view, the first polishing part moves vertically closer to the substrate than the second polishing part, so that only the first polishing part contacts the substrate to polish the substrate.

15. A method of manufacturing a display, comprising:
forming a display device on a carrier substrate;
separating the display device from the carrier substrate;
removing a residual layer on the carrier substrate by a chemical mechanical polishing apparatus;
removing an outer portion which remains at an edge portion on the carrier substrate by the chemical mechanical polishing apparatus;
forming a new display device on the carrier substrate.

16. The method of claim 15, wherein
the chemical mechanical polishing apparatus includes a first polishing part and a second polishing part, and
the removing the residual layer includes polishing the carrier substrate with the first polishing part and the second polishing part.

17. The method of claim 16, wherein the removing the outer portion includes moving the first polishing part vertically closer to the carrier substrate than the second polishing part, so that only the first polishing part polishes the carrier substrate to remove the outer portion.

18. The method of claim 15, wherein the outer portion has a higher height than the residual layer.

19. The method of claim 15, further comprising:
loading the carrier substrate on a conveyer belt before removing the residual layer,
wherein the removing the residual layer and the removing the outer portion are performed while the carrier substrate is transferred by the conveyer belt.

20. The method of claim 19, further comprising:
attaching a supporting part adjacent to the carrier substrate on the conveyer belt to compensate for a step with the carrier substrate.

21. The method of claim 15, wherein
the chemical mechanical polishing apparatus comprises a conveyor belt to transfer the carrier substrate, a polishing head disposed on the conveyor belt, and a body part which moves the polishing head and supplies a slurry to the polishing head, and
the polishing head comprises a first polishing part, a second polishing part, and a second slurry outlet formed between the first polishing part and the second polishing part,
wherein the method further comprising moving the first polishing part and the second polishing part independently of each other in a direction substantially perpendicular to the carrier substrate.

22. The method of claim 15, further comprising:
forming the first polishing part to have a cylindrical shape, and
forming the first polishing part and the second polishing part rotatable together or respectively.

23. The method of claim 15, wherein forming the display device comprises:
forming a plurality of insulating layers, thin film transistors, circuit lines, organic light emitting diodes on the carrier substrate.
